(19) United States
(12) Patent Application Publication
(10) Pub. No.: US 2005/0210650 A1
(43) Pub. Date: Sep. 29, 2005

(54) System and method for disassembling scrapped vehicle

(76) Inventor: Won Bae Lee, Seoul (KR)

Correspondence Address: MORGAN, LEWIS & BOCKIUS LLP (SF), 2 PALO ALTO SQUARE, PALO ALTO, CA, 94306, US

(21) Appl. No.: 11/010,008

(22) Filed: Dec. 10, 2004

(30) Foreign Application Priority Data
Mar. 27, 2004 (KR) 2004-0021004

(51) Int. Cl. G01R 1/00; B07B 13/00

(52) U.S. Cl. 29/403.3; 29/403.1; 29/426.3; 29/710; 29/791

(57) ABSTRACT

The present invention relates to a system and method for disassembling scrapped vehicles in which multiple process-based facilities are provided in series on one path for performing each disassembling process from a loading process of a scrapped vehicle to a final vehicle body compression process. The scrapped vehicles are moved along the path while mounted on a truck that moves the vehicles via a transfer rail. The truck that has completed a transfer is lowered into the interior of a tunnel beneath the path and transferred back to the position where the first process was performed.

### CROSS-REFERENCE TO RELATED APPLICATIONS

This application claims priority to Korean Application No. 10-2004-0021004, filed on Mar. 27, 2004, the disclosure of which is incorporated fully herein by reference.

### FIELD OF THE INVENTION

The present invention relates to a system and a method for disassembling a scrapped vehicle, and in particular to a system and a method for disassembling a scrapped vehicle in which multiple process-based facilities are provided in series on one path for performing each disassembling process from a loading process of a scrapped vehicle to a final vehicle body compression process.

### BACKGROUND OF THE INVENTION

As personal vehicles become more and more indispensable as daily means of transportation, the number of vehicles has been on the increase, and the number of vehicles that have been scrapped is on the increase as well.

Since scrapped vehicles are of little economical value because they are comprised of parts which are very old or beyond their expected lives, prearrangement appears essential to recycle reusable parts of the scrapped vehicles. However, most prearranging processes depend on labor-intensive work, and thus the cost involved in recycling and scrapping vehicles is usually very high. In addition, the life cycles of second hand parts are relatively short, so the second hand parts can be used in general for only a very limited period of time. Furthermore, frequent replacement of vehicles due to shortened launching periods of new products also restricts compatibility of the second hand parts.

On average, 75% parts by weight of scrapped vehicles are recycled. Considering the complexity of the structure of the scrapped vehicles, the recycling rate is relatively high in comparison with other consumption goods. While ferrous or non-ferrous metals have been recycled, the remaining materials of about 25% have not been buried under the ground. The process of the scrapped vehicle is roughly classified into a collecting process of reusable parts and a shredding process of unrecyclable parts.

The infrastructure for the process of scrapped vehicles is well developed in small countries such as Japan and European countries. For example, there are about 3,000 to 4,000 companies involved in processing the scrapped vehicles in Germany. In comparison, there are only about 10,000 of such companies in the U.S. In most foreign companies for processing the scrapped vehicles, the second hand parts are effectively recycled through the on-line system.

According to recent environment-related regulations on recycling of scrapped vehicles in the European Union, the manufacturer of a vehicle is responsible for collecting all scrapped vehicles, including buses, with the capacity of below 9 passengers and trucks with capacity below 3.5 total weight bearing the cost at their end, which have been manufactured and sold since Jul. 1, 2002. With respect to vehicles sold before Jul. 1, 2002, the collecting responsibility will be upon the manufacturers as of Jan. 1, 2007.

Ideally, in the collection and scrapping of all used vehicles, manufacturers should construct a scrapping system having same capacity of manufacturing. Therefore, problems arise if manufacturers use conventional scrapping systems and methods without suitable modifications. For example, a conventional disassembling system for a scrapped vehicle is illustrated in FIG. 2. The conventional disassembling system is provided with various facilities that are randomly arranged on the ground within a certain area. The facilities and processes are complicated and require a relatively large space. Because the disassembling facilities are randomly spread throughout a wide space, disassembling parts requires lengthy periods of time, which result in increased cost. Furthermore, safety problems abound in the current disassembling processes.

### SUMMARY OF THE INVENTION

It is an object of the present invention to provide a system and a method for disassembling a scrapped vehicle in which multiple process-based facilities are provided in series on one path for performing each disassembling process and a truck is provided for moving the scrapped vehicle along the line, whereby it is possible to compact a working site and facilities, to improve efficiency of the scrapping work with minimum labor.

The present invention teaches a system and method for disassembling scrapped vehicles. The scrapped vehicles are seated on a truck and moved on a transfer rail along a facility line along which each disassembling process is sequentially performed. The truck that completes a transfer of the scrapped vehicles to a final process station continues on the transfer rail through an underground tunnel and returns back to the first process station.

One embodiment of the present invention comprises multiple process-based facilities disposed in series on one path, a rail arranged along the line, a truck traveling on the rail while accommodating a scrapped vehicle thereon, and a truck returning system, in which the truck that completes a transfer of the scrapped vehicles to a final process station, enters a tunnel formed underground, and returns back to the first process station along a transfer rail in the tunnel.

In another embodiment of the present invention, the process-based facilities are installed for sequentially performing the following steps of: checking disassembling objects; preparing the objects; eliminating explosive parts; collecting liquid; disassembling external parts; disassembling internal parts; dismounting engine, transmission, exhaust system, and chassis; and compressing a body of a vehicle.

In yet another embodiment of the present invention, the truck returning system comprises a tunnel for moving the truck therein. The tunnel includes two vertical paths extending downward from both ends of the rail and a horizontal path connecting the vertical paths to each other, a transfer rail that is installed along the interior of the pit for transferring the truck, and an elevator for lifting or lowering the truck in the vertical paths of the tunnel.

In a further embodiment of the present invention, the elevator comprises an extending rail being connecting to the ends of the rail on the ground of the working site and to the ends of the transfer rail in the tunnel.

In yet a further embodiment of the present invention, the truck returning system further comprises a truck transferring device including a chain connecting the truck and a winding device. The winding device being positioned at one end of the tunnel where a first process station is located and the winding device pulls the truck to a location below the first process station by winding the chain.

### BRIEF DESCRIPTION OF THE DRAWINGS

The aforementioned aspects and other features of the present invention will be explained in the following description, taken in conjunction with the accompanying drawings, wherein:

FIG. 1 is a view illustrating a conventional disassembling procedure of a scrapped vehicle;

FIG. 2 is a plane view illustrating a conventional disassembling system of a scrapped vehicle;

FIG. 3 is a perspective view illustrating a disassembling system of a scrapped vehicle according to the present invention; and

FIGS. 4A and 4B are views illustrating a driving state of a disassembling system of a scrapped vehicle according to the present invention.

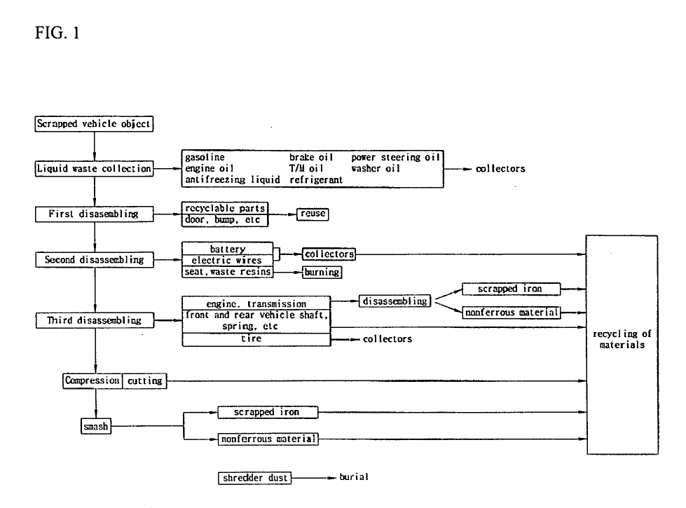

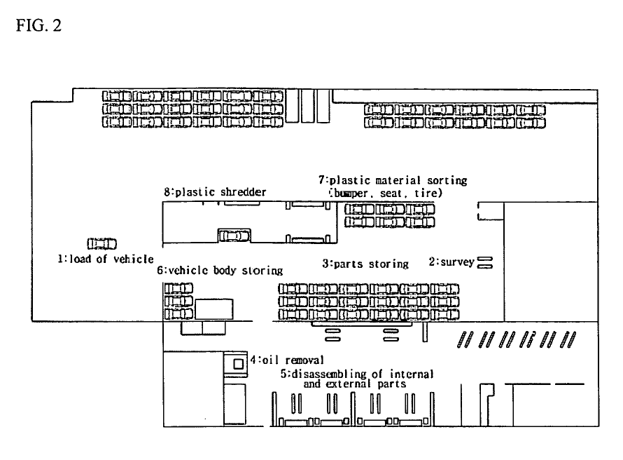

### DETAILED DESCRIPTION OF THE EMBODIMENTS

The preferred embodiments of the present invention will be described with reference to the accompanying drawings.

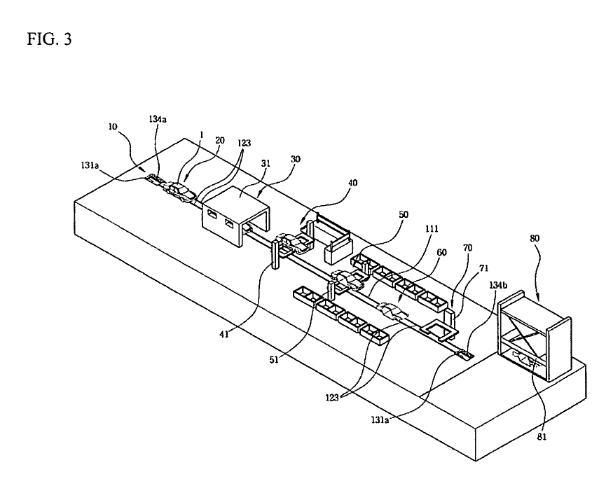

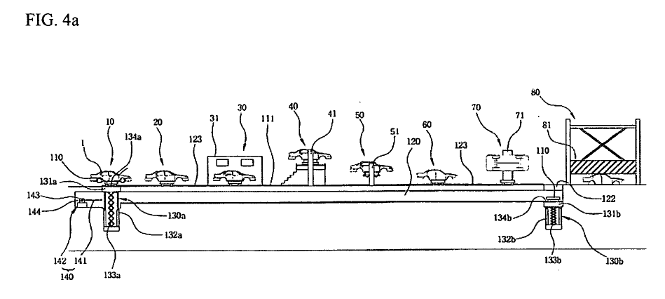

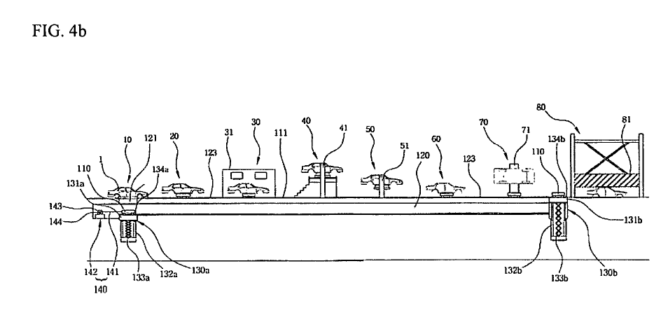

FIG. 3 is a perspective view illustrating a system for disassembling scrapped vehicles according to the present invention, and FIGS. 4A and 4B are views illustrating a driving state of a system for disassembling scrapped vehicles according to the present invention.

Referring to FIG. 3, the system according to the present invention is implemented in the following example sequence: checking disassembling objects 10, preparing the vehicle 20, eliminating explosive parts 30, collecting liquids 40, disassembling external parts 50, disassembling internal parts 60, dismounting engine, transmission, exhaust system, and chassis 70, and compressing the body of a vehicle 80. This sequence of processes is performed along one path.

Referring now to FIG. 4a, when checking disassembling objects 10, the scrapped vehicle 1 is mounted on a truck 110 using a forklift 1, and the disassembling object parts are checked and recorded before the disassembling procedures are performed (disassembling work order sheet is made). In the preparing step 20, the scrapped vehicle 1, including tires, hood, and battery, is disassembled.

When eliminating explosive parts 30, explosive parts are first removed in order to prevent any damage on workers or disassembling devices before recyclable parts are disassembled. Various airbags (airbags in the side of driver's seat and passenger's seats, side airbags, curtain airbags) or seat free tensioners are connected to an explosive part, and are thus processed at this station. A screen automatic door system adapted to aid entry into the vehicle 1, a soundproof device for preventing sound during explosion, and a duct device for sucking explosion gases are provided.

In the liquid collection step 40, the vehicle 1 is mounted on a lift 41 together with the truck 110, and over 95-98% of fuel, engine oil, anti-freezing solution, brake oil, power steering oil, transmission oil, refrigerant, and washer liquid are collected. In the disassembling of external and disassembling of internal parts 50 and 60, the reuse or recyclable parts are collected from the vehicle 1. Over 200 to 250 parts, such as trim parts, cover parts, and seat parts, are collected. The vehicle 1 is mounted on the table lift 51 together with the truck 110, and the external parts, such as glass, are dissembled, and the vehicle 1 is moved to the disassembling step 60 together with the truck 110, and then the seat, trim parts, gauge parts and peripheral parts are disassembled.

In the engine, transmission, exhaust system, chassis parts disassembling step 70, the engine and partial chassis parts are disassembled using a vehicle body rotation device 71. When the above parts are collected, the steel material parts, consumable parts still remaining in the vehicle body (plastic materials less than 50 g, rubber parts) and the full-length parts that could not be reused and could not be recyclable are left. In the compressing a body of a vehicle step 80, the vehicle body is lifted up from the truck 110 together with the remaining parts and is moved and placed in the compression press 81 and is compressed.

The above disassembling processes are sequentially performed while truck 110 and scrapped vehicles 1 are being moved along transfer rail 111. In the present invention, the process-based facilities 10 through 81 adapted to perform each disassembling procedure from the loads of the scrapped vehicles to the final vehicle body compression procedures are arranged in series, and transfer rail 111 is installed on the ground so that truck 110 is moved along each facility.

In one embodiment, there is provided a truck returning system in which truck 110, after completing the transfer of the scrapped vehicle up to the final compressing a body of vehicle 80 is returned to the checking disassembling objects 10 through tunnel 120 below the path along which truck 110 moved the scrapped vehicles (hereinafter “scrap process path”). Truck return transfer rail 123 is installed in the interior of the tunnel 120.

In the truck returning system, the truck returning line includes vertical paths 121 and 122 extending downward from the scrap process path from both ends of the transfer rail 111, a tunnel 120 that connects the two vertical paths 121 and 122 at a certain depth below the scrap process path, truck return transfer rail 123 that is capable of moving truck 110 in the interior of tunnel 120, and lifting and lowering devices 130a and 130b that lift and lower truck 110 in the interior of vertical paths 121 and 122.

When the vehicle body is moved to compression press 81, an empty truck is left. At this location, vertical path 122 is formed at the end of transfer rail 111 in which empty truck 110 is positioned. In addition, vertical path 121 is formed at the location that the checking disassembling objects 10 starts, namely, at the opposite end of transfer rail 111. Tunnel 120 connecting vertical paths 121 and 122 is formed at a certain depth below the scrap process path, and truck return transfer rail 123 is installed in the interior of tunnel 120 through which truck 110 is moved.

In one embodiment, transfer rail 111 and truck return transfer rail 123 form a continuous loop along the surface of the ground, through vertical path 122, then through tunnel 120, and finally through vertical path 121.

In another embodiment, transfer rail 111 and truck return transfer rail 123 are disconnected from each other. Lifting and lowering devices 130a and 130b are installed in vertical paths 121 and 122 for lifting and lowering truck 110 between the scrap process path and tunnel 120. Lifting and lowering devices 130a and 130b include bases 131a and 131b on which truck 110 is positioned, hydraulic cylinders 132a and 132b for lifting and lowering supports 131a and 131b, and supports 133a and 133b for supporting the bases 131a and 131b. Rails 134a and 134b are installed on the upper surfaces of the bases 131a and 131b for easily mounting truck 110 by connecting both ends of transfer rail 111 of the upper side and truck return transfer rail 123 in tunnel 120.

In an embodiment of the present invention, in the truck returning system, there is further provided truck transferring device 140 for automatically transferring through tunnel 120 empty truck 110 from a location beneath where the compressing a body of a vehicle 80 is performed, to a location beneath where the disassembling object part check process step 10 is performed.

In another embodiment, the truck returning system includes chain 141, one end of which is connected to truck 110, and the other end of which is connected to winding device 142 that is installed at one end of tunnel 120. Winding device 142 winds chain 141 and transfers truck 110. Here, winding device 142 includes motor 143 that provides a rotational force, and winding shaft 144 that is installed at a rotary shaft of the motor 143 and winds chain 141 opposite to the truck using the rotational force of the motor.

After the compressing a body of a vehicle step 80 is performed, empty truck 110 is moved to rail 134b of the upper surface of base 131b of lowering device 130b and is automatically lowered together with base 131b by the operation of hydraulic cylinder 132b, and is moved to truck return transfer rail 123 of tunnel 120. At this time, chain 141 is connected to empty truck 110 and winding device 142 operates on chain 141 so that truck 110 is transferred to a location beneath where the checking disassembling objects step 10 is performed. When empty truck 110 arrives at rail 134a of the upper surface of base 131a of opposite lifting device 130a, chain 141 is disconnected from truck 110, and truck 110 is lifted to the surface. Truck 110 is then moved to the area in which the checking of disassembling objects 10 is performed.

As described above, in the present invention, the process-based facilities adapted to perform each disassembling process from the first load of the scrapped vehicles to the final vehicle body compression process are installed along one path in series, so that each disassembling process of the scrapped vehicles is sequentially performed while the scrapped vehicles are being moved along the facility lines while mounted on the truck. Therefore, the facilities and processes are not as complicated as the conventional system for disassembling scrapped vehicles. In the present invention, the disassembling processes are performed by sequentially moving the scrapped vehicles along each line using the truck without using the forklift except for the steps in which the scrapped vehicles are mounted on the truck before the disassembling object part check process is performed, and the remaining vehicle body is placed into the compression press. The use of a movable truck enhances efficiency, and a large scale operation could be achieved with relatively small crew of workers.

Additionally, the truck that completed the transfer of the scrapped vehicle up to the final process is descended into the tunnel formed in the lower side and is moved to the first process along the transfer rail in the tunnel and is ascended to the upper side, thereby successfully returning the truck to the starting point of the process. In the present invention, it is possible to easily adjust the scrapped vehicle process capacity based on the numbers of trucks and workers.

The foregoing description, for purposes of explanation, used specific examples to provide a thorough understanding of the invention. However, it will be apparent to one skilled in the art that the invention is not limited to these examples. The embodiments were chosen and described in order to best explain the principles of the invention and its practical applications, to thereby enable others skilled in the art to best utilize the invention and various embodiments with various modifications as are suited to the particular use contemplated. Thus, the foregoing disclosure is not intended to be exhaustive or to limit the invention to the precise forms disclosed. Many modifications and variations are possible in view of the above teachings.

It is intended that the scope of the invention be defined by the following claims and their equivalents.

1. A system for disassembling scrapped vehicles, comprising:
multiple process-based facilities disposed in series on one path for each disassembling process;
a rail arranged along the line, the rail being disposed above a working site;
a truck traveling on the rail while accommodating a scrapped vehicle thereon; and
a truck returning system, in which the truck that completes a transfer of the scrapped vehicles to a final process station returns back to the first process station.

2. The system of claim 1, wherein said process-based facilities for disassembling a scrapped vehicle are installed for sequentially performing the steps of checking disassembling objects, preparation step, eliminating explosive parts, collecting liquid, disassembling external parts, disassembling internal parts, dismounting engine/transmission/exhaust system/chassis, and compressing a body of a vehicle, in this order.

3. The system of claim 1, wherein said truck returning system further comprising:
a tunnel for communicating the truck therein, the tunnel comprising two vertical paths downwardly extended from both ends of the rail and horizontal path connecting the vertical parts to each other;
a transfer rail that is installed along the interior of the tunnel for transferring the truck thereon; and
elevators for lifting and lowering the truck in the vertical paths of the pit.

4. The system of claim 3, wherein said elevators comprise an extending rail connected to the ends of the rail on the ground of the working site and to the ends of the transfer rail in the pit.

5. The system of claim 3, wherein said truck returning system further comprises a truck transferring device comprising:
a chain, one end of which is connected to the truck; and
a winding device to which the other end of the chain is coupled, the winding device being positioned at one end of the tunnel where a first process station is located, wherein the winding device pulls the truck through the tunnel to the first process station by winding the chain.

6. A method for disassembling scrapped vehicles comprising steps of:
mounting a scrapped vehicle on a truck that moves along a rail;
disassembling the parts of the vehicle while moving the truck through each process-based facility; and
returning the truck back to a first process station after completing the transfer of the scrapped vehicle to a final process station.

7. The method of claim 6, wherein said disassembling step is achieved by sequentially performing the process of checking disassembling objects, preparation step, eliminating explosive parts, collecting liquid, disassembling external parts, disassembling internal parts, dismounting engine/transmission/exhaust system/chassis, compressing a body of a vehicle in this order.

8. A system for disassembling scrapped vehicles, comprising:
multiple process-based facilities disposed in series on one path for each disassembling process;
a rail positioned along the path in the configuration of a loop;
and a truck traveling along the rail, such that the truck, after delivering a vehicle to the last facility, travels back to the first facility along the rail.
